(19) United States
(12) Patent Application Publication
(10) Pub. No.: US 2016/0104859 A1
(43) Pub. Date: Apr. 14, 2016

(54) ORGANIC LIGHT EMITTING DIODE DISPLAY

(71) Applicant: SAMSUNG DISPLAY CO., LTD., Yongin-City (KR)

(72) Inventors: Se IL KIM, Hwaseong-si (KR); Young Shin LEE, Asan-si (KR); Jae Goo LEE, Yongin-si (KR)

(21) Appl. No.: 14/722,649

(22) Filed: May 27, 2015

(30) Foreign Application Priority Data
Oct. 8, 2014 (KR) 10-2014-0136207

(51) Int. Cl. H01L 51/52; H01L 27/32

(52) U.S. Cl. CPC H01L 51/5228; H01L 27/3246; H01L 27/3248; H01L 2251/301; H01L 2251/306; H01L 2251/308; H01L 2251/303

(57) ABSTRACT

An organic light emitting diode display includes a transistor, a first electrode connected to the transistor, a pixel definition layer on the first electrode, and an organic emission layer on the first electrode and corresponding to the emission region. The pixel definition layer exposes an emission region corresponding to a portion of the first electrode. The display also includes an auxiliary conductive pattern, a buffer layer, and a second electrode. The auxiliary conductive pattern does not overlap the emission region and is on the pixel definition layer. The buffer layer covers the organic emission layer and the pixel definition layer and contacts the auxiliary conductive pattern. The second electrode is on the buffer layer.

### CROSS-REFERENCE TO RELATED APPLICATION

Korean Patent Application No. 10-2014-0136207, filed on Oct. 8, 2014, and entitled, “Organic Light Emitting Diode Display,” is incorporated by reference herein in its entirety.

### BACKGROUND

1. Field

One or more embodiments described herein relate to an organic light emitting diode display.

2. Description of the Related Art

An organic light emitting diode display uses organic light emitting diodes (OLEDs) to generate an image. Each OLED emits light from an organic emission layer located between first and second electrodes. The direction in which the light is emitted may determine the type of display being implemented.

For example, in a front emission type of display, the second electrodes of the OLEDs may be made of transparent conductive oxide such as indium tin oxide. The organic emission layer of each OLED is formed, for example, by a deposition process taking unique organic material characteristics into consideration. The second electrode may be formed throughout a substrate including the OLED, for example, by a supporting process taking the unique transparent conductive oxide characteristics into consideration.

### SUMMARY

In accordance with one or more embodiments, an organic light emitting diode display includes a substrate; a transistor on the substrate; a first electrode connected to the transistor; a pixel definition layer on the first electrode and exposing an emission region corresponding to a portion of the first electrode; an organic emission layer on the first electrode and corresponding to the emission region; an auxiliary conductive pattern which does not overlap the emission region and which is on the pixel definition layer; a buffer layer covering the organic emission layer and the pixel definition layer and contacting the auxiliary conductive pattern; and a second electrode on the buffer layer.

The auxiliary conductive pattern may be between the buffer layer and the pixel definition layer. The auxiliary conductive pattern may contact the pixel definition layer. The auxiliary conductive pattern may be between the buffer layer and the second electrode. The auxiliary conductive pattern may contact the second electrode.

The auxiliary conductive pattern may have a smaller work function than the second electrode. The auxiliary conductive pattern may have a lower electrical resistance than the second electrode. The auxiliary conductive pattern may include silver. The second electrode may include a first oxide. The first oxide may include at least one of ITO, IZO, or ZnO.

The second electrode may be a sputtered layer on the buffer layer. The buffer layer may include a second oxide. The second oxide may include at least one of tungsten oxide or a molybdenum oxide. The organic emission layer may include a first organic layer on the first electrode; a main emission layer on the first organic layer; and a second organic layer on the main emission layer.

In accordance with one or more other embodiments, an organic light emitting diode display includes a substrate; a transistor on the substrate; a first electrode connected to the transistor; an organic emission layer on the first electrode; an auxiliary conductive layer on the organic emission layer; a buffer layer on the organic emission layer and contacting the auxiliary conductive layer; and a second electrode on the buffer layer.

The auxiliary conductive layer may be between the buffer layer and the organic emission layer. The auxiliary conductive layer may contact the organic emission layer. The auxiliary conductive layer may be between the buffer layer and the second electrode. The auxiliary conductive layer may contact the second electrode. The auxiliary conductive layer may have a smaller work function than the second electrode.

### BRIEF DESCRIPTION OF THE DRAWINGS

Features will become apparent to those of skill in the art by describing in detail exemplary embodiments with reference to the attached drawings in which:

FIG. 1 illustrates an embodiment of an organic light emitting diode display;

FIGS. 2 and 3 illustrate profiles of damage to an organic emission layer;

FIG. 4 illustrates another embodiment of an organic light emitting diode display;

FIG. 5 illustrates another embodiment of an organic light emitting diode display; and

FIG. 6 illustrates another embodiment of an organic light emitting diode display.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout. Embodiments may be combined to form additional embodiments.

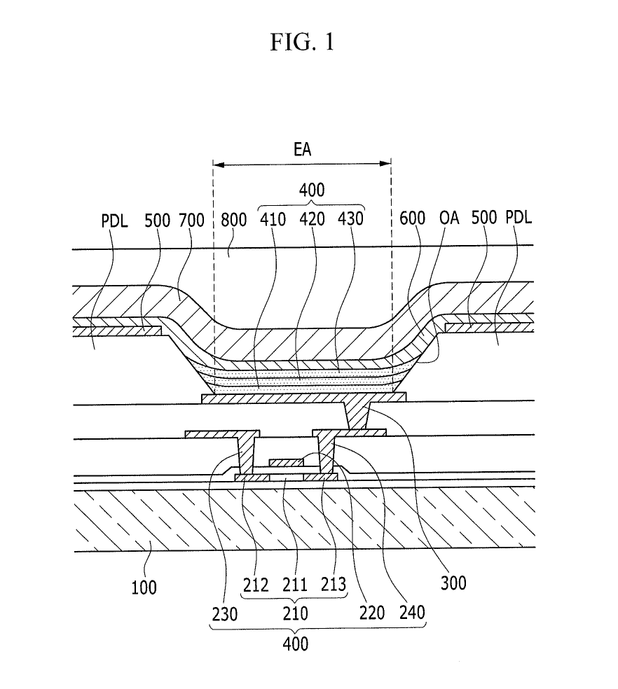

FIG. 1 illustrates an embodiment of an organic light emitting diode display which includes a substrate 100, a thin film transistor 200, a first electrode 300 a pixel definition layer PDL, an organic emission layer 400, an auxiliary conductive pattern 500, a buffer layer 600, a second electrode 700, and an encapsulation layer 800.

The substrate 100 is an insulating substrate including glass, a polymer, stainless steel, or another material. The substrate 100 may be flexible, stretchable, foldable. bendable, and/or rollable. When the substrate 100 is flexible, stretchable, foldable, bendable, and/or rollable, the light emitting display may be entirely or partially flexible, stretchable, foldable, bendable, and/or rollable.

The thin film transistor 200 is on the substrate 100 and functions as a driving thin film transistor or a switching thin film transistor. In FIG. 1, for convenience of description, only one thin film transistor is illustrated with the understanding that the organic light emitting diode display (e.g., a pixel circuit of the display) may include a plurality (e.g., 2, 3, 4, 5, 6, 7, or more) thin film transistors and at least one capacitor. The thin film transistors and at least one capacitor may be connected in various ways.

The thin film transistor 200 includes an active layer 210, a gate electrode 220, a source electrode 230, and a drain electrode 240. The active layer 210 is on the substrate 100 and, for example, may include polysilicon or an oxide semiconductor. The oxide semiconductor may include, for example, an oxide of zinc (Zn), gallium (Ga), tin (Sn), or indium (In), or complex oxides such as zinc oxide (ZnO), indium-gallium-zinc oxide (InGaZnO₄), indium-zinc oxide (In—Zn—O), or zinc-tin oxide (Zn—Sn—O).

The active layer 210 includes a channel region 211 that may or may not be doped with an impurity, and a source region 212 and a drain region 213 at respective sides of the channel region 211. The source and drain regions 212 and 213 are doped with the impurity. The impurity may be different, for example, according to a kind of transistor. Examples include an N-type impurity or a P-type impurity. When the active layer 210 includes an oxide semiconductor, a separate protective layer may be added to protect the oxide semiconductor from being weakened from various environment influences, such as but not limited to high temperatures on the active layer 210.

The gate electrode 220 is on the channel region 211 of the active layer 210. The source electrode 230 and the drain electrode 240 are respectively connected to the source region 212 and the drain region 213 of the active layer 210 through contact holes in the insulating layer.

The first electrode 300 is on the substrate 100. The first electrode 300 is connected to the drain electrode 240 of the thin film transistor 200 through the contact hole in the insulating layer. The first electrode 300 is an anode of a hole injection electrode and is a light reflection electrode. The first electrode 300 may include at least one conductive layer. For example, the first electrode 300 may include a single layer or a multi-layer including at least one of indium tin oxide (ITO), indium zinc oxide (IZO), magnesium silver (MgAg), aluminum (Al), or silver (Ag). The first electrode 300 may include a conductive material having a higher work function than the second electrode 700, in order to increase a electron injection capacity for the organic emission layer 400.

The pixel definition layer PDL is on the first electrode 300 and covers the end of the first electrode 300. The pixel definition layer PDL includes an opening OA exposing a portion, (e.g., a center portion) of the first electrode 300. The opening OA of the pixel definition layer PDL exposes an emission region EA of the first electrode 300. The organic emission layer 400 may emit light corresponding to the emission region EA of the first electrode 300 through the opening OA.

The organic emission layer 400 is on the first electrode 300 at a position corresponding to the emission region EA of the first electrode 300. The organic emission layer 400 may include, for example, a low-molecular organic material or a high-molecular organic material such as poly(3,4-ethylenedioxythiophene) (PEDOT).

The organic emission layer 400 includes a first organic layer 410 on the first electrode 300, a main emission layer 420 on the first organic layer 410, and a second organic layer 430 on the main emission layer 420. The first organic layer 410 may be a multilayer including at least one of a hole injection layer (HIL) or a hole transport layer (HTL). The second organic layer 430 may be a multilayer including at least one of an electron transport layer (ETL) or an electron injection layer (EIL). In another exemplary embodiment, the first organic layer 410 and the second organic layer 430 may be formed throughout the substrate 100 while passing through the emission region EA.

The main emission layer 420 may include a red organic emission layer emitting red light, a green organic emission layer emitting green light, and a blue organic emission layer emitting blue light. The red organic emission layer, the green organic emission layer, and the blue organic emission layer are respectively formed in a red pixel, a green pixel, and a blue pixel which emit light to generate a color image. The main emission layer 420 may implement the color image, for example, by integrally laminating the red organic emission layer, the green organic emission layer, and the blue organic emission layer in the red pixel, the green pixel, and the blue pixel, and by respectively forming a red color filter, a green color filter, and a blue color filter in each pixel.

In another example, the main emission layer 420 may include a white organic emission layer formed of the red pixel, the green pixel, and the blue pixel. A red color filter, a green color filter, and a blue color filter may be respectively formed for each pixel to implement a color image.

When the color image is implemented using a white organic emission layer as the main emission layer 420 with the color filter(s), a deposition may not be required for depositing the red organic emission layer, the green organic emission layer, and the blue organic emission layer on individual pixels, e.g., the red pixel, the green pixel, and the blue pixel.

In another example, the white organic emission layer serving as the main emission layer 420 may be formed to have a single organic emission layer, and may further include a configuration in which a plurality of organic emission layers are laminated to emit white light. For example, the main emission layer 420 may include a configuration in which at least one yellow organic emission layer and at least one blue organic emission layer are combined to emit white light, a configuration in which at least one cyan organic emission layer and at least one red organic emission layer are combined to emit white light, or a configuration in which at least one magenta organic emission layer and at least one green organic emission layer are combined to emit white light.

The organic emission layer 400 may be formed on the emission region EA of the first electrode 300, for example, by a deposition process using a mask such as a fine metal mask (FMM) based on one or more organic material characteristics.

The auxiliary conductive pattern 500 does not overlap the emission region EA of the first electrode 300 exposed by the opening OA of the pixel definition layer PDL, and is positioned on the pixel definition layer PDL. The auxiliary conductive pattern 500 may be positioned at an uppermost layer of the pixel definition layer PDL. The auxiliary conductive pattern 500 is between the pixel definition layer PDL and the buffer layer 600, and contacts the pixel definition layer PDL and the buffer layer 600. The auxiliary conductive pattern 500 may include a material which, for example, has a smaller work function than the second electrode 700, and has lower electrical resistance than the second electrode 700.

The auxiliary conductive pattern 500 may include, for example, a silver-based material, e.g., magnesium silver (MgAg), silver (Ag), or silver magnesium (AgMg). The auxiliary conductive pattern 500 may be formed on the pixel definition layer PDL by the deposition process using the mask covering the emission region EA or by a printing process.

The buffer layer 600 covers the organic emission layer 400 and the pixel definition layer PDL, and contacts with the auxiliary conductive pattern 500. The buffer layer 600 is between the auxiliary conductive pattern 500 and the second electrode 700, and respectively contacts the auxiliary conductive pattern 500 and the second electrode 700. The buffer layer 600 may cover the organic emission layer 400 on the emission region EA of the first electrode 300 and may be simultaneously formed throughout the substrate 100. The buffer layer 600 may include an oxide, e.g., at least one of tungsten oxide (WO₃) or a molybdenum oxide (MoOx). The buffer layer 600 may be formed on the organic emission layer 400 by the deposition process.

The second electrode 700 is on the buffer layer 600. The second electrode 700 is a cathode serving as an electron injection electrode and is a light transmission electrode. The second electrode 700 is positioned throughout the entire substrate 100 to cover the buffer layer 600. The second electrode 700 may include at least one transparent conductive oxide. For example, the second electrode 700 may be a single layer or multilayer which includes at least one of indium tin oxide (ITO), indium zinc oxide (IZO), or zinc oxide (ZnO). The second electrode 700 may be formed on the buffer layer 600 using a sputtering process based on one or more characteristics of the transparent conductive oxide.

In the organic light emitting diode display, light emitted from the organic emission layer 400 is reflected by the first electrode 300 of the light reflection electrode and passes through the second electrode 700 of the light transmission electrode. As a result, the light is emitted in the direction of the encapsulation layer 800. Thus, the organic light emitting diode display is a front emission type.

The encapsulation layer 800 is on the second electrode 700 and encapsulates elements such as the organic emission layer 400 between the substrate 100 and the encapsulation layer 800, as well as the substrate 100. The encapsulation layer 800 may be formed, for example, by alternately depositing at least one organic layer and at least one inorganic layer. The organic layer of the encapsulation layer 800 may include, for example, a polymer. In one embodiment, the organic layer may be a single layer of a laminated layer formed of one of polyethylene terephthalate, polyimide, polycarbonate, epoxy, polyethylene, or polyacrylate. In another embodiment, the organic layer of the encapsulation layer 800 may include polyacrylate, and, for example, a material in which a monomer composition including diacrylate-based monomers and triacrylate-based monomers is polymerized.

The inorganic layer of the encapsulation layer 800 may be a single layer or a laminated layer including, for example, a metal oxide or a metal nitride. In one embodiment, the inorganic of the encapsulation layer 800 may include at least one of a silicon nitride (SiNx), alumina (Al₂O₃), a silicon oxide (SiOx), or titanium oxide (TiO₂). The uppermost part of the encapsulation layer 800 externally exposed may be formed of the inorganic layer to prevent external moisture from permeating. The encapsulation layer 800 may include, for example, at least one sandwich structure including at least one organic layer between at least two inorganic layers.

In another exemplary embodiment, the encapsulation layer 800 may be formed of an encapsulation substrate. In this case, the encapsulation layer 800 is combined to the substrate 100, for example, using a sealant (e.g., frit) to encapsulate the organic emission layer 400 along with the substrate 100.

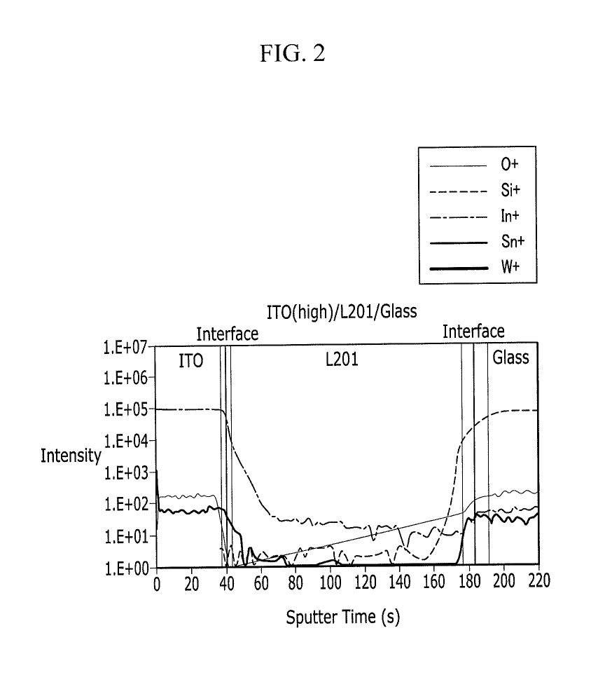

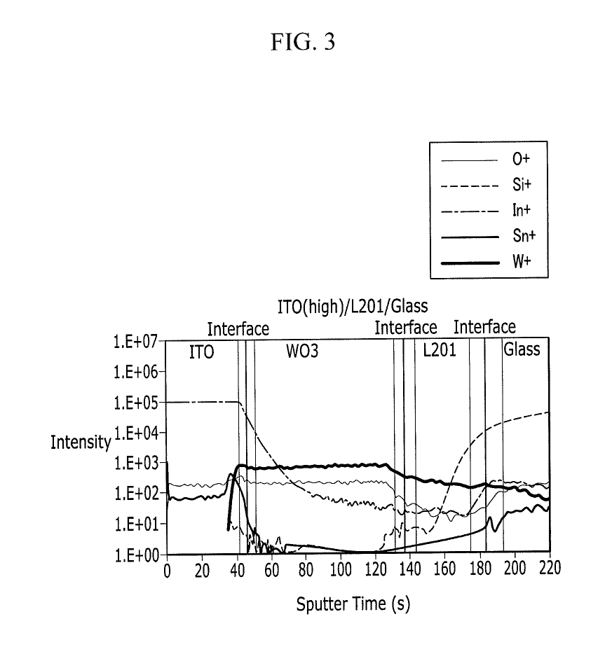

FIG. 2 is a graph corresponding to one type of proposed organic light emitting diode display in which the first electrode, the organic emission layer, and the second electrode are sequentially deposited. FIG. 3 is a graph corresponding to an embodiment of an organic light emitting diode display.

When the second electrode includes indium tin oxide (ITO), the second electrode may be formed by using the sputtering process. However, the organic emission layer may be damaged during the sputtering process. For example, the organic emission layer may be deposited with indium (In) ions and/or tin (Sn) ions in the chamber used to perform the sputtering process. As a result, the emission characteristics of the entire organic emission layer may deteriorate or otherwise may be adversely affected.

FIGS. 2 and 3 illustrate SIMS analysis profiles that confirm damage to the organic emission layer. As illustrated in FIG. 2, the analysis results of the organic emission layer in the proposed organic light emitting diode display show that an indium ion (In⁺ ion) component exists in the electron transfer layer L201 of the second organic layer. These results may confirm that the damage has occurred to the electron transfer layer L201 during sputtering of the indium tin oxide of the second electrode to the electron transfer layer L201.

To reduce or prevent this damage, the organic light emitting diode display according to one embodiment forms the buffer layer 600 on the organic emission layer 400. As illustrated in FIG. 3, the analysis results for the organic emission layer 400 of this embodiment show a substantial reduction in the indium ion (In⁺ ion) component in the electron transfer layer L201 of the second organic layer 430 compared with FIG. 2.

For example, before sputtering occurs, the buffer layer 600 made of WO₃ is formed on the organic emission layer 400. The second electrode 700 of ITO is then formed on the organic emission layer 400 using the sputtering process. As a result, the organic emission layer 400 may be protected from damage (e.g., by ions forming the second electrode 700) by the existence of the buffer layer 600.

Also, by positioning the buffer layer 600 between the second electrode 700 and the organic emission layer 400, electrical resistance of the second electrode 700 may be increased. However, the auxiliary conductive pattern 500 having the smaller electrical resistance than the second electrode 700 contacts the buffer layer 600. As a result, the increase of electrical resistance by the buffer layer 600 is suppressed.

Also, since the auxiliary conductive pattern 500 has a lower work function than the second electrode 700, the electron injection capacity of the second electrode 700 for the organic emission layer 400 is improved. Accordingly, the driving voltage for controlling the emission of the organic emission layer 400 may be decreased. Thus, including the buffer layer 600 and the auxiliary conductive pattern 500 allows the organic light emitting diode display to achieve improved overall driving efficiency, for example, through a reduction in the driving voltage controlling the emission of organic emission layer 400.

Also, since the auxiliary conductive pattern 500 does not overlap the emission region EA and, in one embodiment, is only positioned on the pixel definition layer PDL, any deterioration in the luminance of light emitted from the organic emission layer 400 is suppressed by the auxiliary conductive pattern 500. In another embodiment, the auxiliary conductive pattern 500 may overlap other areas.

Thus, since the auxiliary conductive pattern 500 is positioned to not overlap the emission region EA in which the light of the organic emission layer 400 is emitted, the organic light emitting diode display may achieve improved emission efficiency.

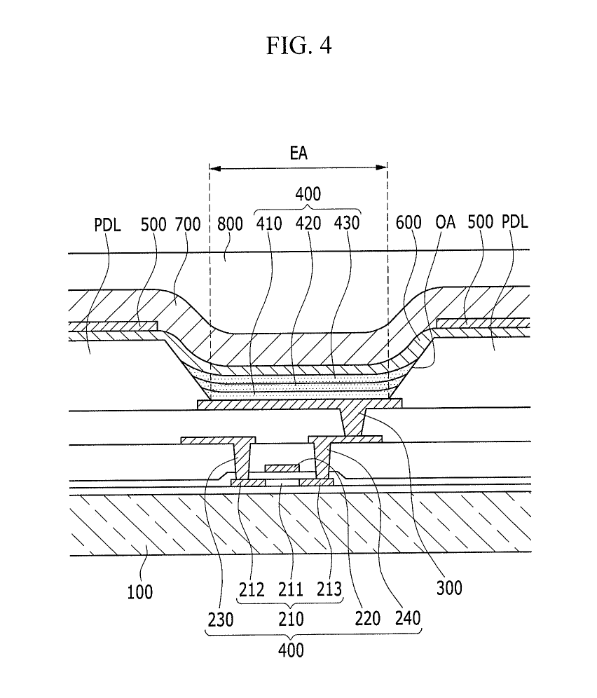

FIG. 4 illustrates another embodiment of an organic light emitting diode display. In this embodiment, the auxiliary conductive pattern 500 does not overlap the emission region EA of the first electrode 300 exposed by the opening OA of the pixel definition layer PDL, and is positioned on the pixel definition layer PDL. The auxiliary conductive pattern 500 is between the buffer layer 600 and the second electrode 700, and contacts the second electrode 700 and the buffer layer 600.

The auxiliary conductive pattern 500 may include a material having a lower work function than the second electrode 700 and having a lower electrical resistance than the second electrode 700. The auxiliary conductive pattern 500 may include, for example, a material which includes silver (Ag), e.g., magnesium silver (MgAg), silver (Ag), or silver magnesium (AgMg). The auxiliary conductive pattern 500 may be formed on the buffer layer 600, for example, by using the printing process or a deposition process using the mask covering the emission region EA.

The buffer layer 600 covers the organic emission layer 400 and the pixel definition layer PDL and contacts the auxiliary conductive pattern 500. The buffer layer 600 is between and contacts the auxiliary conductive pattern 500 and the pixel definition layer PDL. The buffer layer 600 covers the organic emission layer 400 on the emission region EA of the first electrode 300, and may be simultaneously formed throughout the entire substrate 100. The buffer layer 600 includes, for example, an oxide, e.g., at least one of tungsten oxide (WO₃) or a molybdenum oxide (MoOx). The buffer layer 600 may be formed on the organic emission layer 400 by using a deposition process.

The second electrode 700 is on the buffer layer 600 and the auxiliary conductive pattern 500. The second electrode 700 is the cathode that serves as the electron injection electrode and is the light transmission electrode. The second electrode 700 is positioned throughout the entire substrate 100 to cover the buffer layer 600 and the auxiliary conductive pattern 500. The second electrode 700 may include at least one transparent conductive oxide. For example, the second electrode 700 may be formed of a single layer or multilayer including at least one of indium tin oxide (ITO), indium zinc oxide (IZO), or zinc oxide (ZnO). The second electrode 700 may be formed on the buffer layer 600 and the auxiliary conductive pattern 500 by a sputtering process based on one or more characteristics of the transparent conductive oxide.

Thus, by including the buffer layer 600, the organic emission layer 400 is protected from damage during the formation process of the second electrode 700.

Also, by positioning the buffer layer 600 between the second electrode 700 and the organic emission layer 400, electrical resistance of the second electrode 700 may be increased. However, the auxiliary conductive pattern 500 having the smaller electrical resistance than the second electrode 700 contacts the buffer layer 600 and the second electrode 700. As a result, an increase in electrical resistance is suppressed by the buffer layer 600.

Also, since the auxiliary conductive pattern 500 has a lower work function than the second electrode 700, the electron injection capacity of the second electrode 700 for the organic emission layer 400 is improved. Accordingly, a driving voltage controlling the emission of the organic emission layer 400 may be decreased.

As described above, by including the buffer layer 600 and the auxiliary conductive pattern 500, an organic light emitting diode display may be provided with improved driving efficiency since the driving voltage controlling emission of the organic emission layer 400 is decreased.

Also, since the auxiliary conductive pattern 500 does not overlap the emission region EA and, for example, may only positioned on the buffer layer 600 on the pixel definition layer PDL, the luminance of light emitted from the organic emission layer 400 is suppressed from being deteriorated by the auxiliary conductive pattern 500.

As described above, since the auxiliary conductive pattern 500 is positioned to not overlap the emission region EA in which the light of the organic emission layer 400 is emitted, a reduction in emission efficiency of light emitted from the organic emission layer 400 is suppressed although the auxiliary conductive pattern 500 is increased.

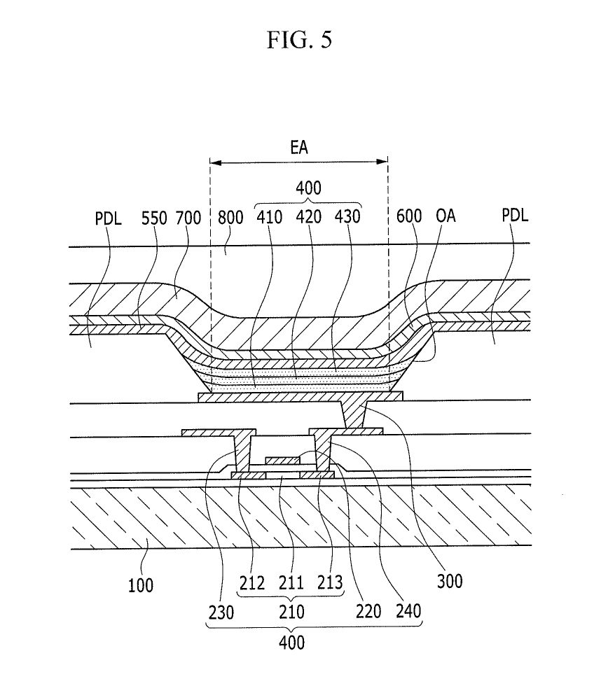

FIG. 5 illustrates another embodiment of an organic light emitting diode display which includes the substrate 100, the thin film transistor 200, the first electrode 300, the pixel definition layer PDL, the organic emission layer 400, an auxiliary conductive layer 550, the buffer layer 600, the second electrode 700, and the encapsulation layer 800.

The auxiliary conductive layer 550 is on the organic emission layer 400. The auxiliary conductive layer 550 is between and contacts the buffer layer 600 and the organic emission layer 400. The auxiliary conductive layer 550 may include a material having a smaller work function than the second electrode 700, and may have a lower electrical resistance than the second electrode 700. The auxiliary conductive layer 550 may include a material including silver (Ag), e.g., magnesium silver (MgAg), silver (Ag), or silver magnesium (AgMg). The auxiliary conductive layer 550 may be formed on the organic emission layer 400 and the pixel definition layer PDL, for example, by using the printing process. The auxiliary conductive layer 550 may have a predetermined thickness, e.g., from 5 Å to 20 Å.

The buffer layer 600 covers and contacts the auxiliary conductive layer 550. The buffer layer 600 is between and contacts the auxiliary conductive layer 550 and the second electrode 700. The buffer layer 600 covers the organic emission layer 400 on the emission region EA of the first electrode 300 and may be simultaneously formed throughout the entire substrate 100. The buffer layer 600 includes the oxide and may include, for example, at least one of tungsten oxide (WO₃) or a molybdenum oxide (MoOx). The buffer layer 600 may be formed on the organic emission layer 400, for example, by using the deposition process. The buffer layer 600 may have a predetermined thickness, e.g., from 700 Å to 900 Å.

The second electrode 700 is on the buffer layer 600. The second electrode 700 is the cathode serving as the electrode injection electrode and the light transmission electrode. The second electrode 700 is positioned throughout the entire substrate 100 to cover the buffer layer 600. The second electrode 700 may include at least one transparent conductive oxide. For example, the second electrode 700 may be formed of the single layer or the multilayer including, for example, at least one of indium tin oxide (ITO). indium zinc oxide (IZO), or zinc oxide (ZnO). The second electrode 700 may be formed on the buffer layer 600 by using the sputtering process based on one or more characteristics of the transparent conductive oxide.

By including the buffer layer 600, the organic emission layer 400 may be protected from damage by the formation process of the second electrode 700.

Also, by positioning the buffer layer 600 between the second electrode 700 and the organic emission layer 400, electrical resistance of the second electrode 700 may be increased. However, the auxiliary conductive layer 550 having a lower electrical resistance than the second electrode 700 contacts the buffer layer 600. As a result, an increase of electrical resistance is suppressed by the buffer layer 600.

Also, since the auxiliary conductive layer 550 has a lower work function than the second electrode 700, the electron injection capacity of the second electrode 700 for the organic emission layer 400 is improved. Accordingly, the driving voltage controlling the emission of the organic emission layer 400 may be decreased. By including the buffer layer 600 and the auxiliary conductive layer 550, since the driving voltage controlling the emission of the organic emission layer 400 is decreased, the organic light emitting diode display may achieve overall improved driving efficiency.

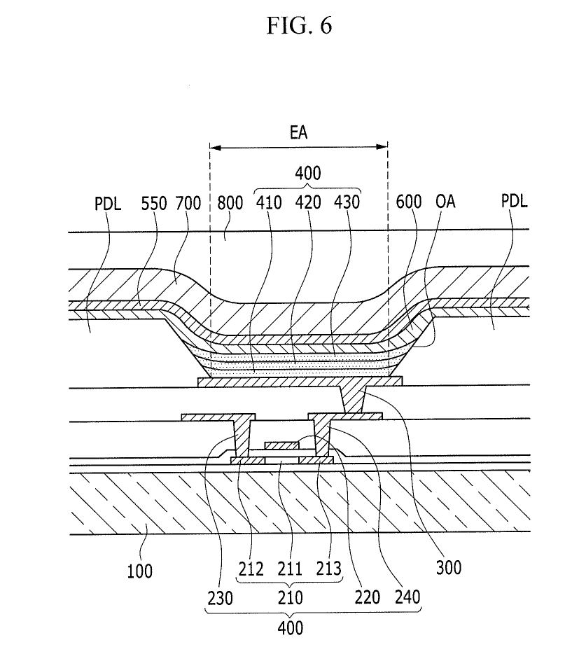

FIG. 6 illustrates another embodiment of an organic light emitting diode display which includes the substrate 100, the thin film transistor 200, the first electrode 300, the pixel definition layer PDL, the organic emission layer 400, the auxiliary conductive layer 550, the buffer layer 600, the second electrode 700, and the encapsulation layer 800.

The auxiliary conductive layer 550 is on the organic emission layer 400 and between and contacts the buffer layer 600 and the second electrode 700. The auxiliary conductive layer 550 may be formed of the material having a smaller work function than the second electrode 700 and a lower electrical resistance than the second electrode 700. The auxiliary conductive layer 550 may be formed of silver (Ag), for example, the auxiliary conductive layer 550 may be formed of magnesium silver (MgAg), silver (Ag), or silver magnesium (AgMg). The auxiliary conductive layer 550 may be formed on the buffer layer 600 by using the printing process. The auxiliary conductive layer 550 may have a predetermined thickness, e.g., from 5 Å to 20 Å.

The buffer layer 600 covers the organic emission layer 400 and the pixel definition layer PDL and contacts the auxiliary conductive layer 550. The buffer layer 600 is between and contacts the auxiliary conductive layer 550 and the organic emission layer 400. The buffer layer 600 covers the organic emission layer 400 on the emission region EA and may be simultaneously formed throughout the entire substrate 100. The buffer layer 600 includes, for example, an oxide, e.g., at least one of tungsten oxide (WO₃) or a molybdenum oxide (MoOx). The buffer layer 600 may be formed on the organic emission layer 400 by using the deposition process. The buffer layer 600 may have a predetermined thickness, e.g., from 700 Å to 900 Å.

The second electrode 700 is on the auxiliary conductive layer 550. The second electrode 700 serves as the cathode as the electron injection electrode and is the light transmission electrode. The second electrode 700 is positioned throughout the entire substrate 100 to cover the auxiliary conductive layer 550. The second electrode 700 may include at least one transparent conductive oxide. For example, the second electrode 700 may be formed of the single layer or the multilayer including at least one of indium tin oxide (ITO), indium zinc oxide (IZO), or zinc oxide (ZnO). The second electrode 700 may be formed on the auxiliary conductive layer 550 by using the sputtering process based on the characteristic of the transparent conductive oxide.

By including the buffer layer 600, the organic emission layer 400 may be protected from damage by the formation process of the second electrode 700.

Also, by positioning the buffer layer 600 between the second electrode 700 and the organic emission layer 400, the electrical resistance of the second electrode 700 may be increased. However, the auxiliary conductive layer 550 having the electrical lower resistance than the second electrode 700 contacts the buffer layer 600 and the second electrode 700. As a result, any increase in electrical resistance by the buffer layer 600 is suppressed.

Also, since the auxiliary conductive layer 550 has a lower work function than the second electrode 700, the electron injection capacity of the second electrode 700 for the organic emission layer 400 is improved. Accordingly, the driving voltage controlling the emission of the organic emission layer 400 may be decreased.

By including the buffer layer 600 and the auxiliary conductive layer 550, since the driving voltage controlling the emission of the organic emission layer 400 is decreased, an organic light emitting diode display with an overall improved driving efficiency is provided.

In another embodiment, the buffer layer 600 may be between the auxiliary conductive layer 550 and the organic emission layer 400, but may not contact one or both of layers 550 and 600.

Example embodiments have been disclosed herein, and although specific terms are employed, they are used and are to be interpreted in a generic and descriptive sense only and not for purpose of limitation. In some instances, as would be apparent to one of skill in the art as of the filing of the present application, features, characteristics, and/or elements described in connection with a particular embodiment may be used singly or in combination with features, characteristics, and/or elements described in connection with other embodiments unless otherwise indicated. Accordingly, it will be understood by those of skill in the art that various changes in form and details may be made without departing from the spirit and scope of the present invention as set forth in the following claims.

What is claimed is:

1. An organic light emitting diode display, comprising:
a substrate;
a transistor on the substrate;
a first electrode connected to the transistor;
a pixel definition layer on the first electrode and exposing an emission region corresponding to a portion of the first electrode;
an organic emission layer on the first electrode and corresponding to the emission region;
an auxiliary conductive pattern which does not overlap the emission region and which is on the pixel definition layer;
a buffer layer covering the organic emission layer and the pixel definition layer and contacting the auxiliary conductive pattern; and
a second electrode on the buffer layer.

2. The display as claimed in claim 1, wherein the auxiliary conductive pattern is between the buffer layer and the pixel definition layer.

3. The display as claimed in claim 2, wherein the auxiliary conductive pattern contacts the pixel definition layer.

4. The display as claimed in claim 1, wherein the auxiliary conductive pattern is between the buffer layer and the second electrode.

5. The display as claimed in claim 4, wherein the auxiliary conductive pattern contacts the second electrode.

6. The display as claimed in claim 1, wherein the auxiliary conductive pattern has a smaller work function than the second electrode.

7. The display as claimed in claim 1, wherein the auxiliary conductive pattern has a lower electrical resistance than the second electrode.

8. The display as claimed in claim 1, wherein the auxiliary conductive pattern includes silver.

9. The display as claimed in claim 1, wherein the second electrode includes a first oxide.

10. The display as claimed in claim 9, wherein the first oxide includes at least one of ITO, IZO, or ZnO.

11. The display as claimed in claim 9, wherein the second electrode is a sputtered layer on the buffer layer.

12. The display as claimed in claim 1, wherein the buffer layer includes a second oxide.

13. The display as claimed in claim 12, wherein the second oxide includes at least one of tungsten oxide or a molybdenum oxide.

14. The display as claimed in claim 1, wherein the organic emission layer includes:
a first organic layer on the first electrode;
a main emission layer on the first organic layer; and
a second organic layer on the main emission layer.

15. An organic light emitting diode display, comprising:
a substrate;
a transistor on the substrate;
a first electrode connected to the transistor;
an organic emission layer on the first electrode;
an auxiliary conductive layer on the organic emission layer;
a buffer layer on the organic emission layer and contacting the auxiliary conductive layer; and
a second electrode on the buffer layer.

16. The display as claimed in claim 15, wherein the auxiliary conductive layer is between the buffer layer and the organic emission layer.

17. The display as claimed in claim 16, wherein the auxiliary conductive layer contacts the organic emission layer.

18. The display as claimed in claim 15, wherein the auxiliary conductive layer is between the buffer layer and the second electrode.

19. The display as claimed in claim 18, wherein the auxiliary conductive layer contacts the second electrode.

20. The display as claimed in claim 15, wherein the auxiliary conductive layer has a smaller work function than the second electrode.
